(19) United States
(12) Patent Application Publication
(10) Pub. No.: US 2026/0025910 A1
(43) Pub. Date: Jan. 22, 2026

(54) SUBSTRATE PACKAGE WITH EFFICIENT SUPPORT FOR SIGNAL ROUTING FOR HIGH DATA RATE APPLICATIONS

(71) Applicant: Marvell Asia Pte Ltd, Singapore (SG)

(72) Inventor: Eldad Bar-Lev, Ramat-Ishay (IL)

(21) Appl. No.: 19/270,764

(22) Filed: Jul. 16, 2025

Related U.S. Application Data
(60) Provisional application No. 63/672,834, filed on Jul. 18, 2024.

(51) Int. Cl. H05K 1/02; H01L 23/36; H05K 1/11; H05K 1/18

(52) U.S. Cl. CPC H05K 1/0243; H01L 23/36; H05K 1/111; H05K 1/181; H05K 2201/10742

(57) ABSTRACT

A device includes a substrate having a first side and a second side, wherein the first side faces opposite the second side. The device also includes a die positioned on the second side of the substrate and electrically coupled to the substrate. The device includes a signal routing component positioned on the first side of the substrate. The signal routing component is configured to route signals between the die and an external component to the device through the substrate. The device includes an electrical board positioned on the second side of the substrate. The electrical board is electrically coupled to the substrate.

### CROSS-REFERENCE TO RELATED APPLICATIONS

This application claims the benefit and priority to the Provisional Application No. 63/672,834 filed on Jul. 18, 2024, which is incorporated herein by reference in its entirety.

### BACKGROUND

Conventional signal routings on a printed circuit board (PCB) on a Ajinomoto Build-up Film (ABF) package are no longer suitable for higher data rates application, higher bandwidth application, and increased ports application. For example, conventional signal routing is no longer suitable for serializer/deserializer (SerDes) with data rates of 224 Gbps pulse amplitude modulation 4-level (PAM4), 448 Gbps PAM4, etc. Additionally, increased bandwidth, e.g., 102.4 Tbps switch with 512×200G ports, for datacenters and artificial intelligence (AI) applications has become prevalent. Conventional signal routing on the PCB is no longer suitable for applications with high data rates, high bandwidth, and/or increased number of ports. Some attempts have been made to route signals for high data rate applications, higher bandwidth applications, high number of port applications, etc. For example, signal may be routed using co-package-copper (CPC), co-package-optics (CPO), etc.

Unfortunately, positioning CPC, CPO, etc., on the substrate uses valuable space (real estate) on the substrate and may result in an increased size of the substrate, e.g., greater than 110 mm×110 mm. A die/chip is usually positioned somewhere in the middle of the substrate with CPC, CPO, etc., positioned on the periphery of the substrate (around the die). However, the die generates a substantial amount of heat that needs to be dissipated, e.g., using a heatsink, etc., to avoid damaging the electrical components. As such, a mechanism to cool the die that is positioned in the middle of the substrate may interfere with CPC, CPO, etc., positioned on the periphery of the substrate.

The foregoing examples of the related art and limitations related therewith are intended to be illustrative and not exclusive. Other limitations of the related art will become apparent upon a reading of the specification and a study of the drawings.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 depicts an example of a side view for a substrate package according to one aspect of the present embodiments.

FIG. 2 depicts an example of a top view for a substrate package according to one aspect of the present embodiments.

FIGS. 3A-3C depicts another example of a side view of the substrate package with a power delivery module according to one aspect of the present embodiments.

FIG. 4 depicts another example of a side view of the substrate package according to one aspect of the present embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Before various embodiments are described in greater detail, it should be understood that the embodiments are not limiting, as elements in such embodiments may vary. It should likewise be understood that a particular embodiment described and/or illustrated herein has elements which may be readily separated from the particular embodiment and optionally combined with any of several other embodiments or substituted for elements in any of several other embodiments described herein. It should also be understood that the terminology used herein is for the purpose of describing certain concepts, and the terminology is not intended to be limiting. Unless defined otherwise, all technical and scientific terms used herein have the same meaning as commonly understood in the art to which the embodiments pertain.

Conventional signal routing such as high speed SerDes signal routing on a PCB results in poor signal integrity and signal loss at higher data rate (e.g., 224 Gbps PAM4, 448 Gbps PAM4, etc.), higher bandwidth (e.g., 102.4 Tbps) and a larger number of ports (e.g., 512×200G ports). CPC connectors, CPO connectors, etc., may be used to reduce signal loss and to improve signal integrity. CPO may integrate optical components such as lasers and modulators onto the same substrate as electrical components such as an application specific integrated circuit (ASICs) within a single package, thereby reducing signal loss and power consumption due to close proximity and resulting in higher bandwidth and improved efficiency. CPC connector may enable connections directly from the top of the chip package, thereby extending the reach of copper and reducing latency and power consumption in comparison to traditional methods. However, CPC connectors, CPO connectors, etc., occupy valuable real estate on a substrate and may interfere with dissipating heat (e.g., using liquid cooling module) from a die positioned on the substrate due to positioning of the CPC connectors, CPO connectors, etc., as well as positioning of the die itself on the substrate, which may result in an increase in size of the substrate to accommodate the positioning of the CPC/CPO connectors.

According to some embodiments, CPC connectors, CPO connectors, etc., used to reduce signal loss and to improve signal integrity may be positioned on a side of the substrate that is opposite to the side where the die is positioned. Accordingly, the real estate on the substrate (on the same side of the substrate that the die is housed) is opened up to be used to house additional dies, larger die, or other electrical components. Accordingly, the compact form factor of the substrate may be maintained while the signal integrity is improved and while signal loss is reduced.

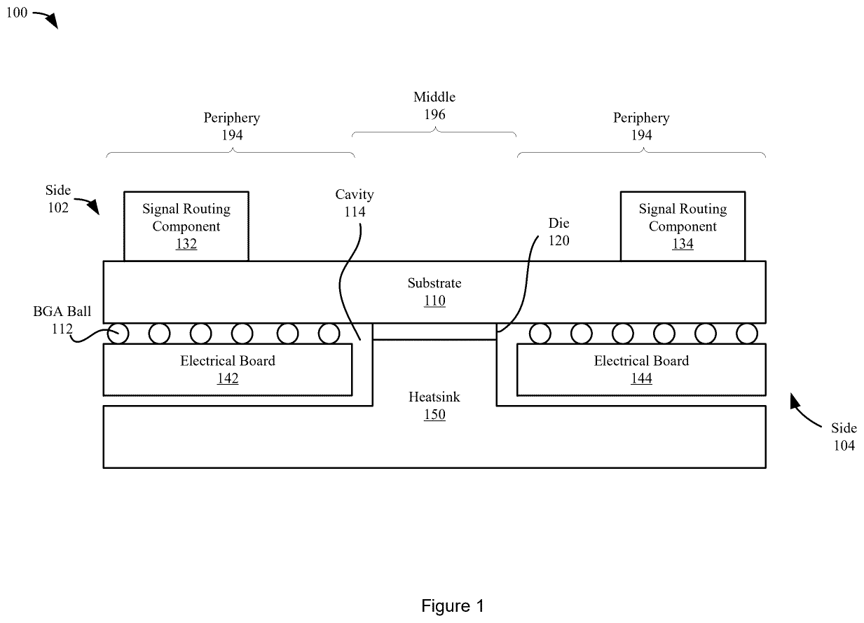

FIG. 1 depicts an example of a side view for a substrate package 100 according to one aspect of the present embodiments. The substrate package 100 includes a substrate 110 having a side 102 and side 104. The sides 102 and 104 face away from one another and are on opposite sides of the substrate 110. The substrate 110 may include a periphery 194 portion and a middle 196 portion. It is appreciated that the periphery 194 portion may refer to the outer portion of the substrate 110 with respect to the middle 196 portion that may refer to the inner portion of the substrate 110. For example, the periphery 194 portion may surround the middle 196 portion. In one nonlimiting example, the substrate 110 may be a flipchip with a plurality of ball grid array (BGA) balls 112 positioned on side 104 of the substrate 110. In one nonlimiting example, the plurality of BGA balls 112 positioned on the side 104 may form a cavity 114. The substrate 110 may include circuit races, pads, vias, and other electrical components. The substrate 110 may facilitate signal transfer to/from other electrical components (e.g., external components to the substrate package 100).

The substrate package 100 also includes a (silicon) die 120 of a chip, which can be but in not limited to an ASIC, a field programmable gate array (FPGA), a processor (e.g., central processing unit (CPU), controller, etc.), etc. The die 120 in one nonlimiting example is positioned on the side 104 of the substrate 110. In one nonlimiting example, the die 120 is positioned in the middle 196 portion of the substrate 110. In one nonlimiting example, the die 120 is positioned within the cavity 114 on the side 104 of the substrate 110. The die 120 may be electrically coupled to the substrate 110.

The substrate package 100 may also include one or more signal routing components 132-134, e.g., CPC, CPO, etc. The signal routing components 132-134 may be positioned on the periphery 194 portion of the substrate 110 on the side 102. As illustrated, the signal routing components 132-134 and the die 120 are housed on the opposite side of the substrate 110. The signal routing components 132-134 are configured to route signals, e.g., optical signal, copper based signal, etc., between a device external to the substrate package 100 and the die 120. The signal routing components 132-134 are configured to route signals to/from the die 120 via the substrate 110.

In one embodiment, the substrate package 100 may also include one or more electrical boards 142-144, e.g., a PCB board. The electrical boards 142-144 may be coupled to the substrate 110 via the side 104 of the substrate 110 and through the plurality of BGA balls 112. In other words, in one nonlimiting example, the electrical boards 142-144 are on the same side 104 of the substrate 110 as the die 120. The plurality of BGA balls 112 is configured to route signals between the substrate 110 and the electrical boards 142-144.

In one embodiment, the substrate package 100 may further include a heatsink 150 to transfer heat away from the die 120. The heatsink 150 may be thermally coupled to the die 120 and may be positioned on the side 104 of the substrate 110. In one nonlimiting example, a cold plate may be used instead of the heatsink 150. When cold plate is used, a liquid cooling module may be used to transfer heat away from the die 120 by allowing liquid coolant to absorb heat and transfer it to a radiator where it is dissipated, e.g., by a fan. According to one nonlimiting example, the heatsink 150 may be a heatsink that transfers heat away from the die 120 using one or more of conduction and convection.

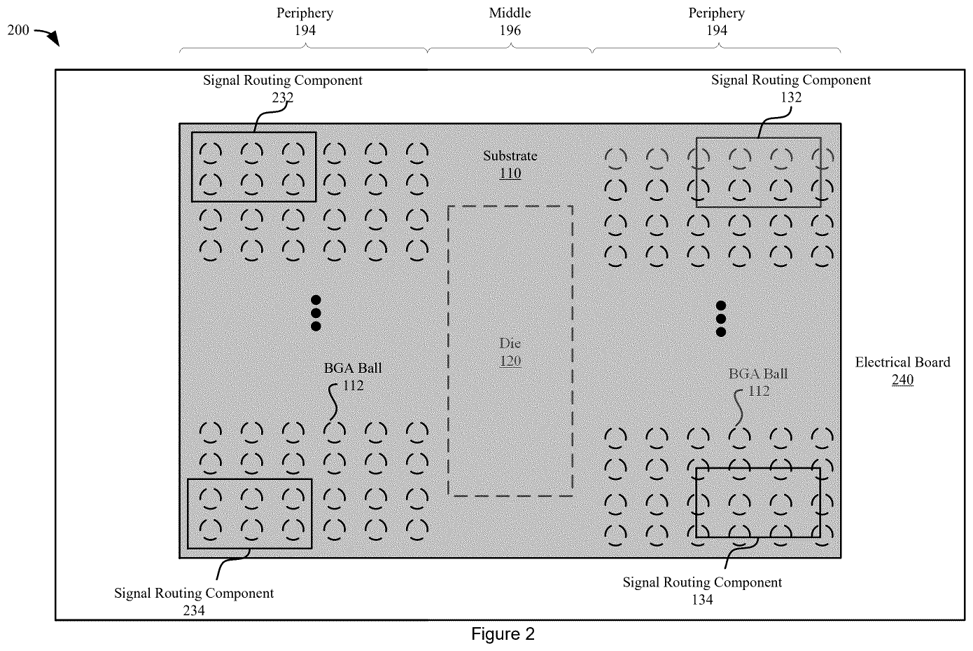

FIG. 2 depicts an example of a top view for a substrate package 200 according to one aspect of the present embodiments. The substrate package 200 is similar to that of FIG. 1. In one nonlimiting example, the substrate package 200 includes signal routing components 232-234 that operate substantially similar to that of signal routing components 132-134. In one nonlimiting example, the substrate package 200 includes an electrical board 240, e.g., a PCB board. It is appreciated that similar to FIG. 1, the die 120 and the signal routing components 132-134, 232-234 are positioned on opposite sides of the substrate 110. For example, the signal routing components 132-134, 232-234 are positioned on side 102 whereas the die 120 is positioned on side 104 of the substrate 110. It is appreciated that the number of signal routing components is shown for illustrative purposes and should not be construed as limiting the scope of the embodiments.

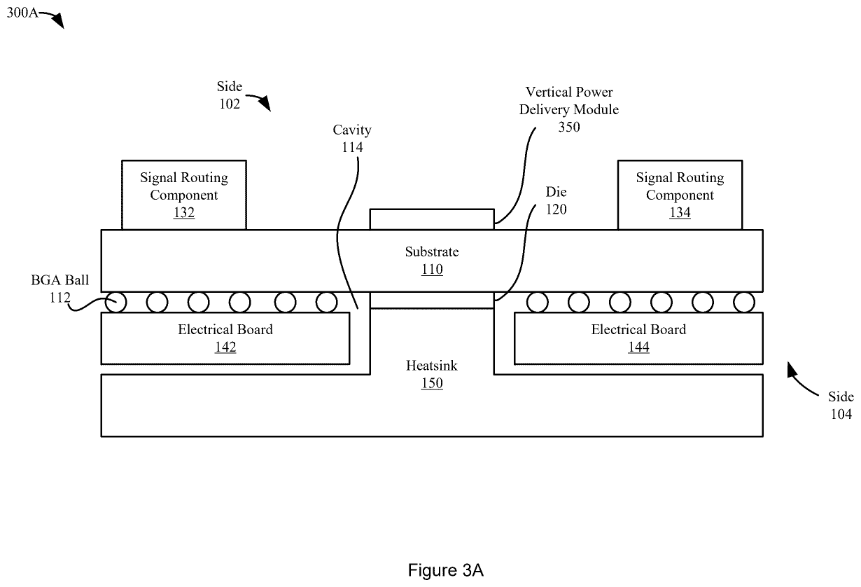

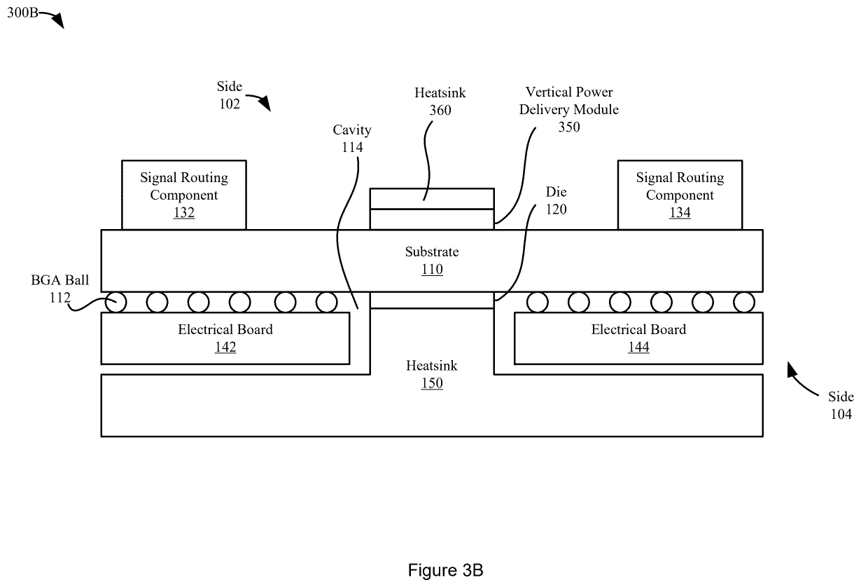

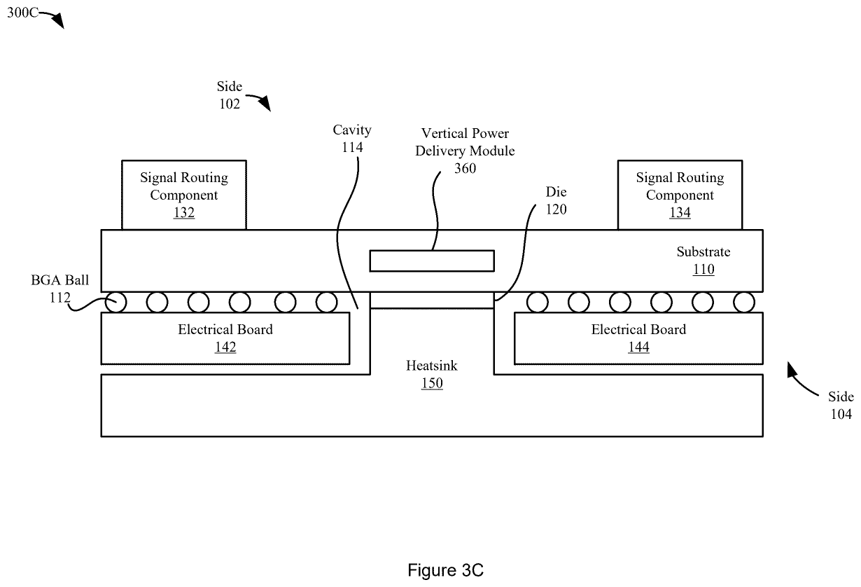

FIGS. 3A-3C depicts another example of a substrate package with a power delivery module according to one aspect of the present embodiments. Referring now to FIG. 3A, a substrate package 300A is shown and is substantially similar to that of FIG. 1. The substrate package 300A may also include a vertical power delivery module 350 positioned on the side 102 of the substrate 110. The vertical power delivery module 350 may have a first side and a second side (the first side and the second side are on opposite sides). The vertical power delivery module 350 is electrically connected to side 102 of the substrate 110 from the first side. The vertical power delivery module 350 is configured to provide power to the die 120 through the substrate 110, thereby providing power to the die 120 more efficiently. The vertical power delivery module 350 may be positioned in the middle 296 portion of the substrate 110. In one nonlimiting example, the vertical power delivery module 350 is positioned symmetrically with respect to the positioning of the die 120 except that the vertical delivery module 350 and the die 120 are positioned on opposite sides of the substrate 110 (e.g., sides 102 and 104).

Referring now to FIG. 3B, the package substrate 300B is similar to that of FIG. 3A. The package substrate 300B further includes a heatsink 360 that is thermally coupled to the vertical power delivery module 350. In one nonlimiting example, since the vertical power delivery module 350 is electrically coupled to the substrate 110 from the first side, the heatsink 360 is thermally coupled to the second side of the vertical power delivery module 350. The heatsink 360 may be similar to the heatsink 150 to transfer heat away from the vertical power delivery module 350 using one or more of conduction, convection, liquid coolant, etc. The heatsink 360 is also positioned on the side 102 of the substrate 110.

Referring now to FIG. 3C, the package substrate 300C is similar to that of FIG. 3A. The package substrate 300C includes a vertical power delivery module 360 that is integrated within the substrate 110. The vertical power delivery module 360 operates similar to that of vertical power delivery module 350.

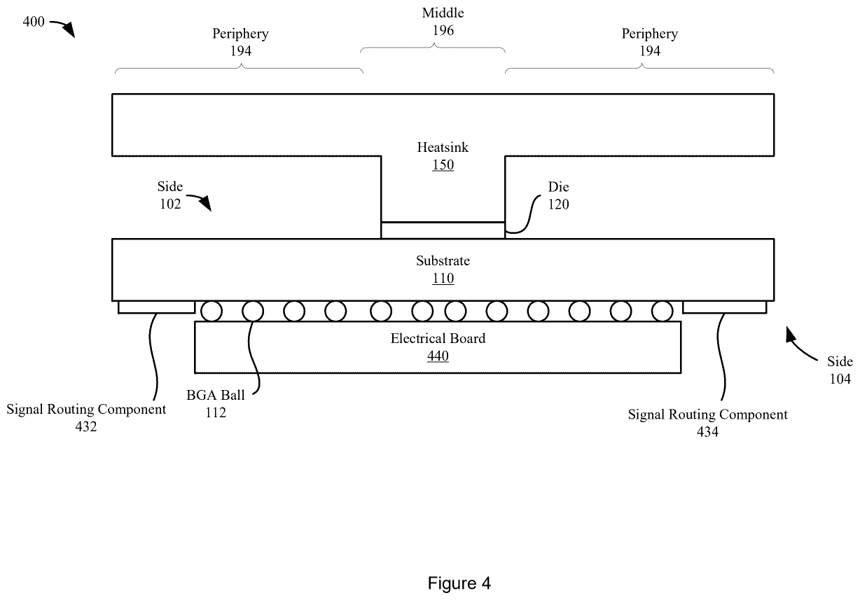

FIG. 4 depicts another example of a substrate package 400 according to one aspect of the present embodiments. The substrate package 400 includes a substrate 110 having a side 102 and side 104. The sides 102 and 104 face away from one another and are on opposite sides of the substrate 110. The substrate 110 may include a periphery 194 portion and a middle 196 portion. The substrate 110 may be a flipchip with a plurality of ball grid array (BGA) balls 112 positioned on side 104 of the substrate 110. It is appreciated that use of BGA balls 112 is for illustrative purposes and should not be construed as limiting the scope of the embodiments. For example, land grid array (LGA), pin grid array (PGA), etc., may similarly be used. In one nonlimiting example, the plurality of BGA balls 112 positioned on the side 104 may form a cavity 114.

In one embodiment, the substrate package 400 also includes a die 120, e.g., ASIC, field programmable gate array (FPGA), processor (e.g., central processing unit (CPU), controller, etc.), etc. The die 120 in one nonlimiting example is positioned on the side 102 of the substrate 110 (instead of being positioned on side 104 of the substrate 110 as it is done in FIG. 1). In one nonlimiting example, the die 120 is positioned in the middle 196 portion of the substrate 110. The die 120 may be electrically coupled to the substrate 110.

In one embodiment, the substrate package 400 may also include one or more signal routing components 432-434, e.g., CPC, CPO, etc., that are similar to the signal routing components 132-134. The signal routing components 432-434 may be positioned on the periphery 194 portion of the substrate 110 on the side 104. As illustrated, the signal routing components 432-434 and the die 120 are housed on the opposite side of the substrate 110. The signal routing components 432-434 are configured to route signals, e.g., optical signal, copper based signal, etc., between a device external to the substrate package 400 and the die 120. The signal routing components 432-434 are configured to route signals to/from the die 120 via the substrate 110.

In one embodiment, the substrate package 400 may also include an electrical board 440, e.g., a PCB board. The electrical board 440 may be coupled to the substrate 110 via the side 104 of the substrate 110 and through the plurality of BGA balls 112. In other words, in one nonlimiting example, the electrical board 440 is on the same side 104 of the substrate 110 as the signal routing components 432-434. The plurality of BGA balls 112 is configured to route signals between the substrate 110 and the electrical board 440.

In one embodiment, the substrate package 400 may further include a heatsink 150 to transfer heat away from the die 120. The heatsink 150 may be thermally coupled to the die 120 and may be positioned on the side 102 of the substrate 110. In one nonlimiting example, a cold plate may be used instead of the heatsink 150 where a liquid cooling module transfers heat away from the die 120 by allowing liquid coolant to absorb heat and transfer it to a radiator where it is dissipated, e.g., by a fan. According to one nonlimiting example, the heatsink 150 may be a heatsink that transfers heat away from the die 120 using one or more of conduction and convection.

As illustrated, positioning the die and the signal routing components on opposite sides of the substrate 110 frees up space for housing additional electrical components, reduces interference between a heat dissipation mechanism from the die and the signal routing components, maintains a compact form factor for the package substrate, and improves thermal performance.

The foregoing description of various embodiments of the claimed subject matter has been provided for the purposes of illustration and description. It is not intended to be exhaustive or to limit the claimed subject matter to the precise forms disclosed. Many modifications and variations will be apparent to the practitioner skilled in the art. Embodiments were chosen and described in order to best describe the principles of the invention and its practical application, thereby enabling others skilled in the relevant art to understand the claimed subject matter, the various embodiments and the various modifications that are suited to the particular use contemplated.

What is claimed is:

1. A device configured to efficiently support signal routing for high data rate applications, the device comprising:
a substrate having a first side and a second side, wherein the first side faces opposite the second side, wherein the substrate has a periphery portion and a middle portion;
a die positioned in the middle portion of the second side of the substrate, wherein the die is on an electrical board electrically coupled to the substrate;
a plurality of signal routing connectors positioned on the periphery portion of the first side of the substrate, wherein the plurality of signal routing connectors is configured to route signals between the die and an external component to the device through the substrate; and
said electrical board positioned on the second side of the substrate, wherein the electrical board is electrically coupled to the substrate.

2. The device of claim 1, wherein the electrical board is a printed circuitry board (PCB).

3. The device of claim 1, wherein a signal routing connector of the plurality of signal routing connectors is a co-package copper (CPC) connector or co-package optic connector (CPO).

4. The device of claim 1, wherein the substrate has a flipchip ball grid array (BGA), and wherein the second side of the substrate comprises a plurality of BGA balls.

5. The device of claim 4, wherein the plurality of BGA balls is coupled to the electrical board.

6. The device of claim 4, wherein the plurality of BGA balls positioned on the periphery of second side of the substrate form a cavity, and wherein the die is positioned within the cavity.

7. The device of claim 1 further comprising a vertical power delivery module positioned in the middle portion on the first side of the substrate, wherein the vertical power delivery module is configured to power the die.

8. The device of claim 1, wherein the vertical power delivery module has a first side and a second side, wherein the first side of the vertical power delivery module faces opposite the second side of the vertical power delivery module, and wherein the first side of the vertical power deliver module is coupled to the first side of the substrate, and wherein the device further comprises a heatsink coupled to the second side of the vertical power delivery module wherein the heatsink is configured to transfer heat away from the vertical power delivery module.

9. The device of claim 1 further comprising a vertical power delivery module integrated within the substrate, wherein the vertical power delivery module is configured to power the die.

10. The device of claim 1 further comprising a heat sink positioned on the second side of the substrate and thermally coupled to the die, wherein the heat sink is configured to transfer heat away from the die.

11. The device of claim 1 further comprising a liquid cooling module positioned on the second side of the substrate and thermally coupled to the die, wherein the liquid cooling module is configured to transfer heat away from the die.

12. A device configured to efficiently support signal routing for high data rate applications, the device comprising:
a substrate having a first side and a second side, wherein the first side faces opposite the second side;
a die positioned on the second side of the substrate and electrically coupled to the substrate;
a signal routing component positioned on the first side of the substrate, wherein the signal routing component is configured to route signals between the die and an external component to the device through the substrate; and
an electrical board positioned on the second side of the substrate, wherein the electrical board is electrically coupled to the substrate.

13. The device of claim 12, wherein the electrical board is a printed circuitry board (PCB).

14. The device of claim 12, wherein the signal routing component is a co-package copper (CPC) connector or co-package optic connector (CPO).

15. The device of claim 12, wherein the substrate is a flipchip ball grid array (BGA), and wherein the second side of the substrate comprises a plurality of BGA balls.

16. The device of claim 15, wherein the plurality of BGA balls is coupled to the electrical board.

17. The device of claim 15, wherein the plurality of BGA balls positioned on the second side of the substrate form a cavity, and wherein the die is positioned within the cavity.

18. The device of claim 12 further comprising a vertical power delivery module positioned on the first side of the substrate, wherein the vertical power delivery module is configured to power the die.

19. The device of claim 12, wherein the vertical power delivery module has a first side and a second side, wherein the first side of the vertical power delivery module faces opposite the second side of the vertical power delivery module, and wherein the first side of the vertical power deliver module is coupled to the first side of the substrate, and wherein the device further comprises a heatsink coupled to the second side of the vertical power delivery module wherein the heatsink is configured to transfer heat away from the vertical power delivery module.

20. The device of claim 12 further comprising a vertical power delivery module integrated within the substrate, wherein the vertical power delivery module is configured to power the die.

21. The device of claim 12 further comprising a heat sink positioned on the second side of the substrate and thermally coupled to the die, wherein the heat sink is configured to transfer heat away from the die.

22. The device of claim 12 further comprising a liquid cooling module positioned on the second side of the substrate and thermally coupled to the die, wherein the liquid cooling module is configured to transfer heat away from the die.

23. The device of claim 12, wherein the die is positioned substantially in a middle of the substrate and wherein the signal routing component is positioned substantially on a periphery of the substrate.

24. A device configured to efficiently support signal routing for high data rate applications, the device comprising:
a substrate having a first side and a second side, wherein the first side faces opposite the second side;
a die positioned on the second side of the substrate and electrically coupled to the substrate;
a signal routing component positioned on the first side of the substrate, wherein the signal routing component is configured to route signals between the die and an external component to the device through the substrate; and
an electrical board positioned on the first side of the substrate, wherein the electrical board is electrically coupled to the substrate.

25. The device of claim 24, wherein the electrical board is a printed circuitry board (PCB), and wherein the signal routing component is a co-package copper (CPC) connector or co-package optic connector (CPO).

26. The device of claim 24, wherein the substrate is a flipchip ball grid array (BGA), and wherein the first side of the substrate comprises a plurality of BGA balls, wherein the plurality of BGA balls is coupled to the electrical board.

27. The device of claim 24 further comprising a vertical power delivery module configured to power the die.

28. The device of claim 24 further comprising a vertical power delivery module integrated within the substrate, wherein the vertical power delivery module is configured to power the die.

29. The device of claim 24 further comprising a heat sink positioned on the second side of the substrate and thermally coupled to the die, wherein the heat sink is configured to transfer heat away from the die.

30. The device of claim 24 further comprising a liquid cooling module positioned on the second side of the substrate and thermally coupled to the die, wherein the liquid cooling module is configured to transfer heat away from the die.
